(19) United States
(12) Patent Application Publication
(10) Pub. No.: US 2024/0118339 A1
(43) Pub. Date: Apr. 11, 2024

(54) SYSTEM, METHOD FOR CIRCUIT VALIDATION, AND SYSTEM AND METHOD FOR FACILITATING CIRCUIT VALIDATION

(71) Applicant: SK hynix Inc., Icheon-si Gyeonggi-do (KR)

(72) Inventors: YU-AN CHEN, Zhubei City Hsinchu County (TW); NY-WEN SHEU, Zhubei City Hsinchu County (TW)

(73) Assignee: SK hynix Inc., Icheon-si Gyeonggi-do (KR)

(21) Appl. No.: 18/355,177

(22) Filed: Jul. 19, 2023

Related U.S. Application Data
(60) Provisional application No. 63/415,166, filed on Oct. 11, 2022.

(30) Foreign Application Priority Data
May 15, 2023 (TW) 112117919

(51) Int. Cl. G01R 31/317

(52) U.S. Cl. CPC G01R 31/31704; G01R 31/31712

(57) ABSTRACT

System, method for circuit validation, and system and method for facilitating circuit validation are provided. The circuit validation system comprises a prototype system and a computing device. The prototype system comprises a programming logic device circuit configured to implement a modified circuit design. The modified circuit design includes a circuit module as a design under test (DUT), an input generation circuit coupled to the circuit module for outputting input signals to the circuit module in response to a test signal, and an output acquisition circuit coupled to the circuit module for storing output data from the circuit module. The computing device is capable of being coupled to the prototype system and configured to generate the test signal to perform a test of the DUT on the prototype system.

### CROSS-REFERENCE TO RELATED APPLICATION

This non-provisional application claims the benefit under 35 U.S.C. § 119(e) of U.S. Provisional Application No. 63/415,166 filed on Oct. 11, 2022, and claims priority under 35 U.S.C. § 119(a) to Taiwanese Patent Application No. 112117919 filed on May 15, 2023, in the Taiwan Intellectual Property Office, the entire contents of which are hereby incorporated by reference.

### BACKGROUND OF THE INVENTION

### 1. Field of the Invention

The present disclosure relates to circuit validation, and in particular to systems and methods for circuit validation and systems and methods for facilitating circuit validation.

### 2. Description of the Related Art

In design of a digital circuit system, circuit validation is a time-consuming and complicated process. A great number of complicated test cases with respect to the digital circuit system are required to be written to ensure maximum coverage of requirements under various levels of requirements specifications, such as functional, software, and user levels.

For example, a sophisticated digital circuit system, such as a communication circuit to be utilized in an electronic device includes respective sub-systems for transmitters and receivers. In addition to dedicated circuits for the sub-systems, a specific type of circuit modules sharing the same or similar dedicated functionality and operations may be employed and disposed in the sub-systems for signal or data processing, or between the sub-systems for signal or data conversion or communication. Further, the digital circuit system may include a plurality of different clock domains and the specific type of circuit modules may be utilized and disposed in different clock domains. For the circumstances in the example illustrated above, verification of a circuit design of the digital circuit system circuit is time-consuming inevitably resulting from the computer simulation running for a great number of complicated test cases. The test coverage for the circuit design may be inadequate due to the sophistication of the digital circuit system involving different levels of circuit hierarchy. In particular, elaborate test cases for the specific type of circuit modules may not be realized suitably in the simulation for the digital circuit system because such kind of test cases may be too complicated and time-consuming to perform.

For example, synchronizers are one type of digital circuit modules designed specifically for signals or data crossing unrelated clock domains in a digital circuit system without issue of metastability. A conventional approach to verify a design of a synchronizer relies on a simulation of the digital circuit system in which test patterns are simulated and it is checked as to whether the synchronizer successfully synchronizes signals or data to a target clock domain in the digital circuit system. This approach provides an excellent way to verify synchronizers because one can easily monitor every detail during the process of synchronization. That means not only verification but also debugging is possible. However, the simulation of the digital circuit system itself is a time-consuming task and if comprehensive verification is wanted, the increasing test patterns would dramatically increase the simulation time as well.

### BRIEF SUMMARY OF THE INVENTION

The following provides technologies for circuit validation, suitable for circuit validation with respect to a circuit module of a digital circuit system.

The following provides various embodiments according to the technologies from different aspects, such systems and methods for circuit validation, and systems and methods for facilitating circuit validation.

The present disclosure provides a system for circuit validation. The system for circuit validation comprises a prototype system and a computing device. The prototype system comprises a programming logic device circuit configured to implement a modified circuit design. The modified circuit design includes a circuit module as a design under test (DUT), an input generation circuit coupled to the circuit module for outputting input signals to the circuit module in response to a test signal, and an output acquisition circuit coupled to the circuit module for storing output data from the circuit module. The computing device is capable of being coupled to the prototype system and configured to generate the test signal to perform a test of the DUT on the prototype system.

The present disclosure provides a method for circuit validation. The method comprises the following operations: using a prototype system comprising a programming logic device circuit configured to implement a modified circuit design including a circuit module as a design under test (DUT), an input generation circuit coupled to the circuit module for outputting input signals to the circuit module in response to a test signal, and an output acquisition circuit coupled to the circuit module for storing output data from the circuit module; and communicating with the prototype system by a computing device configured to generate the test signal to perform a test of the DUT on the prototype system.

In some embodiments of the system for circuit validation or method for circuit validation, the computing device is configured to generate the test signal in form of parameters and send the test signal to the input generation circuit to output the input signals indicating test patterns associated with the parameters for the test of the DUT.

In some embodiments of the system for circuit validation or method for circuit validation, the computing device is configured to read output data associated with the test signal from the output acquisition circuit after the computing device receives a test completion signal from the prototype system so that the computing device is capable of checking the output data associated with the test signal.

In some embodiments of the system for circuit validation or method for circuit validation, the computing device is configured to read output data associated with the test signal from the output acquisition circuit after the computing device receives a test completion signal from the prototype system and to check whether the test of the circuit module is passed based on the output data associated with the test signal and expected results associated with the test.

In some embodiments of the system for circuit validation or method for circuit validation, the prototype system is coupled to the computing device through a signal interface, and the input generation circuit and the output acquisition circuit are coupled to the computing device through the signal interface.

The present disclosure also provides a system for facilitating circuit validation. The system comprises a prototype system which includes a programming logic device circuit configured to implement a modified circuit design. The modified circuit design includes a circuit module as a design under test (DUT), an input generation circuit coupled to the circuit module for outputting input signals to the circuit module in response to a test signal, and an output acquisition circuit coupled to the circuit module for storing output data from the circuit module.

The present disclosure further provides a method for facilitating circuit validation. The method comprises: obtaining, by a computing device, a circuit design of a circuit module; and generating, by a computing device, a modified circuit design of the circuit module, wherein the modified circuit design including the circuit module as a design under test (DUT), an input generation circuit coupled to the circuit module for outputting input signals to the circuit module in response to a test signal, and an output acquisition circuit coupled to the circuit module for storing output data from the circuit module.

In some embodiments of the system or method for facilitating circuit validation, the modified circuit design of the circuit module is generated for configuring a prototype system comprising a programming logic device circuit to implement the modified circuit design.

In some embodiments of the system or method for facilitating circuit validation, the prototype system is configured to be capable of being communicated with a test computing device and configured to perform a test of the DUT on the prototype system in response to a test signal from the test computing device.

In some embodiments of the system or method for facilitating circuit validation, the input generation circuit is configured to receive the test signal in form of parameters and to output the input signals indicating test patterns corresponding to the parameters for the test of the DUT.

In some embodiments of the system or method for facilitating circuit validation, the output acquisition circuit is configured to send output data associated with the test signal after the prototype system sends a test completion signal so that the test computing device is capable of checking the output data associated with the test signal.

### BRIEF DESCRIPTION OF THE DRAWINGS

FIG. 1 is a diagram illustrating architecture of a system for circuit validation with respect to a circuit module of a digital circuit system according to an embodiment, using hardware based on a modified circuit design of the circuit module and software that communicates with the hardware.

FIG. 2 is a diagram illustrating of a method for prototyping a circuit design of a circuit module in a digital circuit system, according to an embodiment.

FIG. 3 is a schematic block diagram illustrating an example of a system for circuit validation with respect to a circuit module according to the architecture of FIG. 1.

FIG. 4 is a flowchart illustrating a process for controlling a test according to an embodiment.

FIG. 5 is a flowchart illustrating a method for circuit validation with respect to a circuit module according to an embodiment.

FIG. 6 is a flowchart illustrating a method for facilitating circuit validation with respect to a circuit module according to another embodiment.

### DETAILED DESCRIPTION OF THE INVENTION

To facilitate understanding of the object, characteristics and effects of this present disclosure, embodiments together with the attached drawings for the detailed description of the present disclosure are provided, the description is as below.

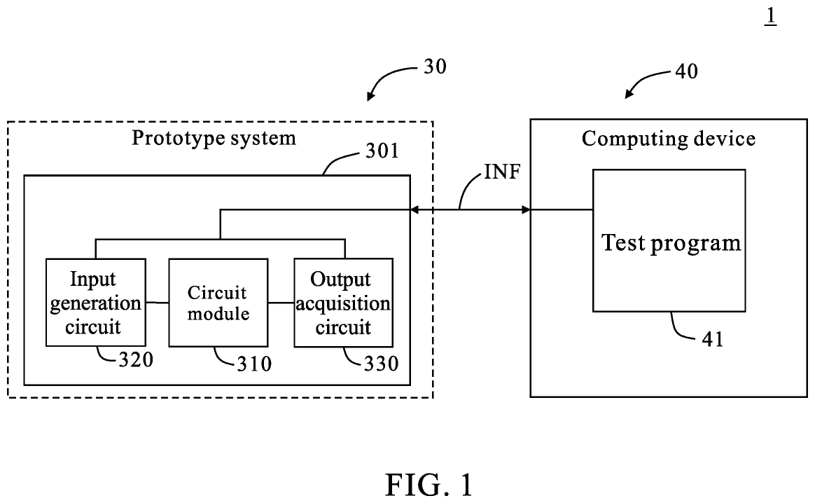

FIG. 1 illustrates architecture of a system for circuit validation 1 with respect to a circuit module (such as a standard cell) of a digital circuit system using hardware based on a modified circuit design of the circuit module and using software that communicates with the hardware, according to an embodiment. As shown in FIG. 1, the system for circuit validation 1 includes a prototype system 30 and a computing device 40. The system for circuit validation 1 is configured to perform circuit validation with respect to a circuit module (or referred to as a design under test (DUT)) of a digital circuit system by using hardware such as the prototype system 30 including at least one programmable logic device (PLD) 301 based on a modified circuit design (e.g., denoted by 310, 320, and 330) of the circuit module (e.g., represented by 310) and by using software such as a test program 41, which can be executed on the computing device 40 and configured to communicate with the prototype system 30 for circuit validation of the circuit module through a signal interface INF.

The exemplary architecture facilitates the prototype system implementing a modified circuit design of a circuit module for circuit validation or verification. To this end, at least one programmable logic device (PLD) 301 can be utilized to form a circuit for the modified circuit design in the PLD 301 including a circuit module 310, an input generation circuit 320, and an output acquisition circuit 330. For example, the input generation circuit 320 is a circuit configured to generate test patterns for the circuit module 310 and the output acquisition circuit 330 is another circuit configured to store output data from the circuit module 310. The exemplary architecture also facilitates the computing device 40 implementing software such as a test program 41 in charge of determining the test patterns for the circuit module 310 and checking the output data acquired from the circuit module 310. This architecture of circuit validation system (or validation platform) leverages the advantages of hardware speedy verification and the flexibility of software. For example, if different DUTs are going to be tested, the software can be revised to adapt the different functionality of a DUT in a short time and for hardware, it is merely replacement of the DUT with the new one.

In the embodiment as illustrated in FIG. 1, the architecture of the system for circuit validation enhances effectiveness and efficiency of circuit validation with respect to a circuit module of a digital circuit system with hardware acceleration and with software flexibility, as compared to circuit validation with respect to the circuit module relying on computer simulation of the entire digital circuit system.

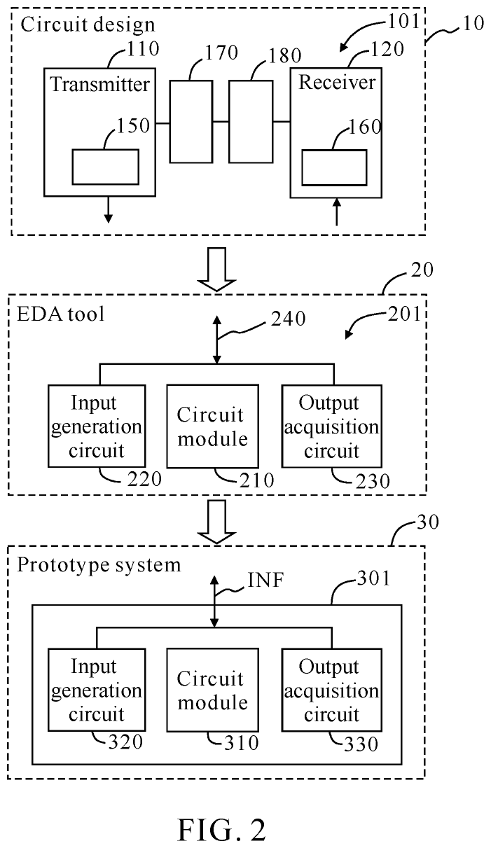

The circuit module or DUT is a portion of a digital circuit system typically. FIG. 2 illustrates a method for prototyping a circuit design of a circuit module in a digital circuit system, according to an embodiment. As shown in FIG. 2, a circuit design 10 describing a digital circuit system 101 is written in a hardware description language (HDL), such as Very High Speed Integrated Circuit (VHSIC) HDL (VHDL), Verilog, SystemVerilog, or so on. The circuit design 10 can be created, edited, modified, simulated, or debugged by using an electronic design automation (EDA) tool 20, which typically includes one or more programs executed in a computing device such as a computer, workstation, server, or a cloud system, or so on. The circuit design 10, for example, describes a digital circuit system 101, such as a communication circuit which is to be utilized in an electronic device and includes respective sub-systems for a transmitter 110 and a receiver 120 to communicate with another electronic device. In addition to dedicated circuits for the sub-systems, a specific type of circuit modules (e.g., first circuit modules 150 and 160; or second circuit modules 170 and 180) sharing the same or similar dedicated functionality and operations. For example, one specific type of circuit modules (e.g., first circuit modules 150 and 160) may be employed and disposed in the sub-systems for signal or data processing such as clock multiplexers, or another specific type of circuit modules (e.g., second circuit modules 170 and 180) may be employed and disposed between the sub-systems for signal or data conversion or communication such as synchronizers. Further, the digital circuit system may include a plurality of different clock domains (e.g., circuits according to different clocks at different frequencies or same frequency with different phases) and the specific types of circuit modules may be utilized and disposed in different clock domains.

In order to utilize a prototype system in the system for circuit validation 1 for a circuit module (e.g., the first circuit module 150 or 160; second circuit module 170 or 180) of the digital circuit system 101, the method for prototyping a circuit design of a circuit module in a digital circuit system (e.g., the communication circuit described by the circuit design 10) includes generating a modified circuit design 201 of a circuit module 210, as illustrated in the middle portion of FIG. 1, and then generating (or configuring) a prototype system 30 realizing the modified circuit design 201 using at least one programmable logic device (PLD) 301, such as a field programmable gate array (FPGA), as illustrated in the lower portion of FIG. 2.

In some embodiments, the generation of the modified circuit design 201 can be performed by using an EDA tool 20 which is configured to obtain a circuit design of a circuit module (e.g., the first circuit module 150 or 160; or second circuit module 170 or 180) and to generate the modified circuit design 201 of the circuit module 210 according to the circuit design of the circuit module.

In one embodiment, obtaining a circuit design of a circuit module includes reading the circuit design 10 of the digital circuit system 101 and extracting a portion of the circuit design 10 (e.g., the first circuit module 150 or 160; or second circuit module 170 or 180) as a circuit design of a circuit module by using an EDA tool 20. For example, extracting a portion of the circuit design 10 can be implemented by separating or selecting the portion of the circuit design 10 from the circuit design 10 by using an EDA tool 20.

In another embodiment, obtaining a circuit design of a circuit module includes reading a circuit design of a circuit module (e.g., the first circuit module 150 or 160; or second circuit module 170 or 180). For example, reading a circuit design of a circuit module can be implemented by loading the circuit design from a library of circuit module or standard cells or storage.

For example, generating the modified circuit design 201 can be implemented by creating a new circuit design including a copy or a modified copy of the circuit design of the circuit module and additional circuitry for facilitating circuit validation by using an EDA tool 20.

The circuit design of the circuit module can be referred to as a design under test (DUT), regardless of the manner of generation. For example, the EDA tool 20 is configured to generate the modified circuit design of the circuit module including the circuit module 210, and additionally including an input generation circuit (e.g., waveform generator) 220 and an output acquisition circuit 230 coupled to the circuit module 210, wherein the circuit module 210 is electrically connected or coupled between the input generation circuit 220 and the output acquisition circuit 230, which are coupled to an signal interface 240 for communication with a test program, such as the test program 41 of the system for circuit validation 1 illustrated in FIG. 1.

In some embodiments, the generation of the modified circuit design 201 as exemplified in the present disclosure can be implemented automatically by using an EDA tool 20 configured with its automation functionality or a script for generating the modified circuit design 201, or even using a program external to the EDA tool for doing this.

The EDA tool 20 can further be configured to generate data required to configure the prototype system 30 to perform operations of the circuit module in terms of physical logic devices, which would be performed inside an integrated circuit to be fabricated for the entire digital circuit system, such as an application specific integrated circuit (ASIC) or a system on a chip (SoC) device. In an embodiment, as shown in the lower portion of FIG. 2, the prototype system 30 is configured using the data required to configure the prototype system 30, which is generated by the EDA tool 20, to implement the modified circuit design 201 by using a programmable logic device (PLD) 301, such as a field programmable gate array (FPGA), to form a circuit in the PLD 301 including a circuit module 310, an input generation circuit 320, and an output acquisition circuit 330, as counterparts of those illustrated in the middle portion of FIG. 2.

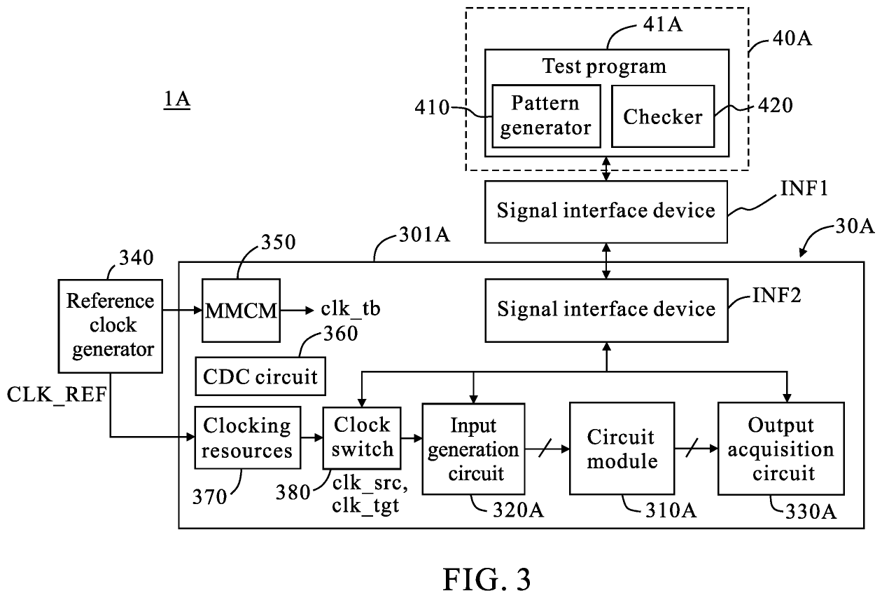

FIG. 3 illustrates an example of a system for circuit validation with respect to a circuit module according to the architecture of FIG. 1. As shown in FIG. 3, a system for circuit validation 1A includes a prototype system 30A and a computing device 40A. The prototype system 30A comprises a programming logic device circuit 301A configured to implement a modified circuit design including a circuit module 310A as a design under test (DUT), an input generation circuit 320A coupled to the circuit module 310A for outputting input signals to the circuit module 310A in response to a test signal, and an output acquisition circuit 330A coupled to the circuit module 310A for storing output data from the circuit module 310A. The computing device 40A is capable of being coupled to the prototype system 30A to communicate with the prototype system 30A for circuit validation through a signal interface compliant with a communication specification such as a Serial Peripheral Interface (SPI), Universal Serial Bus (USB), and so on. For example, the computing device 40A is equipped externally (or internally) with a signal interface device INF1 (e.g., a master SPI device, manufactured by National Instruments (NI) corporation) which is used to connected to a coupled to a signal interface device INF2 (e.g., a slave SPI device, manufactured by NI corporation) equipped in the prototype system 30A. In this manner, the test program 41A is capable of communicating with the prototype system 30A including the input generation circuit 320A and output acquisition circuit 330A so as to generate the test signal or other signal to control or initiate the prototype system 30A to perform a test of the DUT on the prototype system 30A.

Further, in the implementation of the system for circuit validation, additional clocking related circuits may be used because of requirements for a platform adopted for generating the prototype system 30A or requirements for meeting functionality of the DUT. For instance, the prototype system 30A may be implemented by an FPGA platform manufactured by a vendor, such as Xilinx, and the FPGA platform generally requires a reference clock circuit, such as a reference clock generator 340, for providing a reference clock (CLK_REF) for an FPGA board, as an example of the programming logic device circuit 301A, in which the modified circuit design of the circuit module is implemented by using an FPGA. Following this instance, a Mixed-Mode Clock Manager (MMCM) 350, which is provided by Xilinx, serves as a frequency synthesizer, jitter filter, or clock deskew, and can be embedded in the FPGA to generate a required clock (e.g., denoted by clk_tb). In addition, a clock domain crossing (CDC) circuit 360, e.g., based on XPM_CDC by Xilinx, is embedded in the FPGA to secure clock domain crossing. Moreover, clocking resources 370 and a clock switch 380 are used to generate different clocks (e.g., denoted by clk_src and clk_tgt) for source and target clock domains, respectively. For example, the clocks clk_src and clk_tgt are applied to the input generation circuit 320A. It is noted that the above vendor specific implementation examples are optional and the implementation of the system for circuit validation, certainly, can be done according to the architecture as illustrated in FIG. 1, in other approach whenever appropriate.

Regarding the software for circuit validation, the test program 41 or 41A can be implemented to include one or a plurality of software modules or sub-systems for performing functionality for circuit validation. In an example, the test program 41A includes a pattern generator 410 and a checker 420. The pattern generator 410 is configured to generate one or more test signals indicating test patterns in form of parameters and send these parameters through the test signal(s) to the input generation circuit 320A. For example, the input generation circuit 320A can be implemented to include a waveform generator to output the input signals indicating test patterns associated with the parameters for the test of the DUT in response to the test signal(s) from the pattern generator 410. The checker 420 is configured to read output data associated with the test signal(s) from the output acquisition circuit 330A after the computing device 40A (e.g., the test program 41A or the checker 420) receives a test completion signal from the prototype system 30A so that the computing device 40A (e.g., the test program 41A or the checker 420) is capable of checking the output data associated with the test signal(s).

To this end, in some examples, the test program (e.g., 41 or 41A) can be implemented to be capable of receiving one or more test cases or related information by using any appropriate software approach, such as receiving command lines or scripts to define a test case, or creating a test case through a graphical user interface provided by the test program. In general, a test case may be described (but not limited to) by information such as step-up (or pre-requisites), test case description, test steps, test data (or test patterns), expected results. According to information provided in a test case, the test program (e.g., 41 or 41A) can be implemented to be capable of outputting test patterns based on the test case, for example, by using the pattern generator (e.g., 410). In addition, the test program (e.g., 41 or 41A) can further be implemented to be capable of verifying output data associated with the test patterns based on the test case, for example, by using the checker (e.g., 420). In this manner, the test program (e.g., 41 or 41A) can be readily configured for a DUT or adapted for different DUTs for comprehensive circuit validation.

Relying on acceleration of FPGA and flexibility of test software, the coverage of test scenario with respect to the circuit module can be increased dramatically. The failure which is difficult to be detected in simulation of the digital circuit system can be detected in the system for circuit validation based on FIG. 1 with respect to the circuit module.

In addition, the test program implemented as software executable in the computing device for controlling circuit validation, such as including pattern generation or checking functionality or both, offers capability of being rapidly adaptive to the DUT. It helps testing many different DUTs on the system for circuit validation when needed.

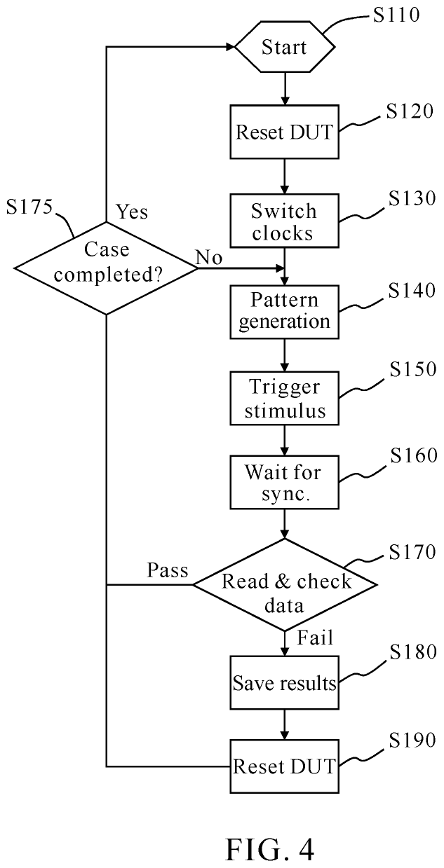

FIG. 4 illustrates a process for controlling a test according to an embodiment. The process can be implemented in a test program (e.g., 41 or 41A) according to the architecture of FIG. 1, such the system for circuit validation 1 or 1A. The process in FIG. 4 provides an example of how the test program controls the prototype system (e.g., 30 or 30A) for a test according to a test case.

In operation S110, the test program starts at waiting for receiving user input indicating one or more test cases, and optionally receiving related information such as repeat times of the test cases. For example, the test program can be implemented by using any appropriate software approach, such as receiving command lines or scripts to define a test case, or creating a test case through a graphical user interface provided by the test program.

In operation S120, the test program resets a DUT in the prototype system (e.g., circuit module 310 or 310A) at the beginning of each test.

In operation S130, the test program changes the clocks for source and target clock domains in the prototype system. For example, in FIG. 3, the test program 41A can be implemented to inform the clock switch 380 to generate different clocks (e.g., clk_src and clk_tgt) for source and target clock domains, respectively, in the prototype system 30A.

In operation S140, the test program generates one or more test patterns in form of parameters and sends these parameters to the input generation circuit in the prototype system. For example, in FIG. 3, the test program 41A can be implemented to send one or more test signals to the input generation circuit 320A (e.g., waveform generator) in the prototype system 30A. For example, the parameters include a first parameter indicating how many data to be synchronized in a case that the DUT is a synchronizer. The parameters may further include a second parameter indicating which piece of data is valid or invalid, where pieces of data for a test pattern each can be set valid or invalid. The parameters may further include a third parameter indicating a length (lasting source clock cycles) for each piece of data. Regarding the parameters for a test, the input generation circuit 320A can be implemented to include a waveform generator that is capable of generating one or more input signals according to the parameters and outputting the input signal(s) to the DUT.

In operation S150, the test program sends a trigger stimulus for a test. For example, the test program sends a command (e.g., by using a test signal indicating an assertion of a command) to allow or trigger the input generation circuit 320A (e.g., waveform generator) to start to feed a test pattern to DUT, wherein the test pattern is generated according to a test signal indicating parameters of a test pattern from the test program 41A, for example.

In operation S160, the test program waits for test completion (e.g., synchronization is done). For example, the test program can be configured to continuously check whether the synchronization is done in a case that the DUT is a synchronizer. For example, an event that “synchronization is done” could be a time-up of a timer. Following this example, a timer can be implemented as a circuit or in a circuit in the prototype system (e.g., 30 or 30A), such as in the input generation circuit (e.g., 320 or 320A) or output acquisition circuit (e.g., 330 or 330A). A test completion signal being asserted indicating that a test is done, for example, is sent from the timer to the computing device (e.g., 40 or 40A) so that the test program (e.g., 41 or 41A) determines whether the test is completed according to the test completion signal.

In operation S170, the test program performs reading and checking data output from the DUT. For example, once the test program (e.g., 41 or 41A) determines that the synchronization is done, it reads back all acquired data output from the DUT stored in the output acquisition circuit (e.g., 330 or 330A) and checks correctness of the read back data. The correctness of the read back data can be determined according to criteria derived from the test case, for example, on values of the read back data or sequence thereof. In an example, a test is done where a test case has an expected result from the DUT “0101” in binary according to a test case and an actual output of the DUT is “0100” in binary. In this example, the test program reads the actual output of the DUT stored in the output acquisition circuit (e.g., 330 or 330A) and determines whether the actual output of the DUT is correct by a criterion based on the actual output and the expected result. For example, the criterion is whether the actual output and the expected result are equal. If they are equal, the test case is passed and operation S175 is performed; otherwise, the test case is failed and operation S180 is performed. In some examples of test cases, the criterion can be specified with a logical expression based on the actual output and the expected result.

In operation S175, the test program checks whether the test is completed. For example, a test may include one or more test cases. If the test is completed, the test program can be configured to perform other operation, such as returning to operation S110l. If the test is not completed, the process proceeds from operation S140 for the next test case.

In operation S180, the test program saves the test results. For example, the test results may include the actual output and whether the test is passed or failed, or further information related.

In operation S190, the test program resets the DUT for the next test case after test results of a test case is saved.

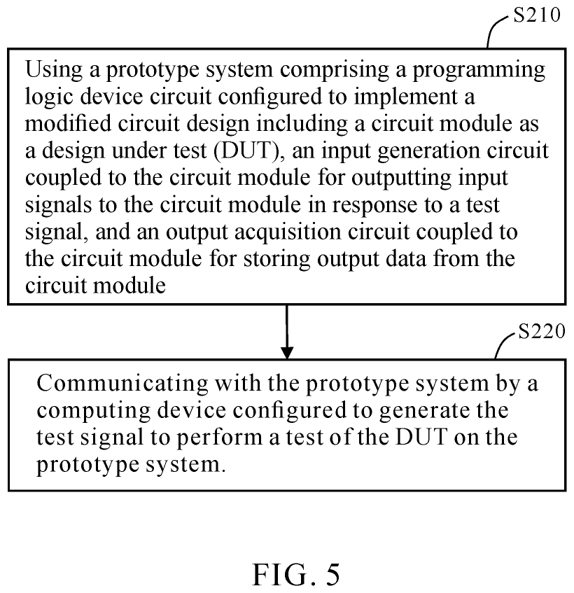

In addition, following embodiments of a method for circuit validation with respect to a circuit module are provided from an aspect of the present disclosure. FIG. 5 illustrates a method for circuit validation with respect to a circuit module according to an embodiment. The method in FIG. 5 is a generalized process including steps S210 and S220.

Step S210 includes using a prototype system (e.g., 30 or 30A) comprising a programming logic device circuit (e.g., 301 or 301A) configured to implement a modified circuit design including a circuit module (e.g., 310 or 310A) as a design under test (DUT), an input generation circuit (e.g., 320 or 320A) coupled to the circuit module for outputting input signals to the circuit module in response to a test signal, and an output acquisition circuit (e.g., 330 or 330A) coupled to the circuit module for storing output data from the circuit module.

Step S220 includes communicating with the prototype system (e.g., 30 or 30A) by a computing device (e.g., 40 or 40A) configured to generate the test signal to perform a test of the DUT on the prototype system (e.g., 30 or 30A).

At step S220, for example, the computing device (e.g., 40 or 40A) can be configured to generate the test signal to perform the test by using a test program (e.g., 41 or 41A). For example, any of the related examples of the test program in the present disclosure can be applied to the method of FIG. 5 as an embodiment of the method, whenever appropriate.

In some embodiments of the method for circuit validation, the computing device (e.g., 40 or 40A) is configured to generate the test signal in form of parameters and send the test signal to the input generation circuit (e.g., 320 or 320A) to output the input signals indicating test patterns associated with the parameters for the test of the DUT.

In some embodiments of the method for circuit validation, the computing device (e.g., 40 or 40A) is configured to read output data associated with the test signal from the output acquisition circuit (e.g., 330 or 330A) after the computing device receives a test completion signal from the prototype system (e.g., 30 or 30A) so that the computing device is capable of checking the output data associated with the test signal.

In some embodiments of the method for circuit validation, the computing device (e.g., 40 or 40A) is configured to read output data associated with the test signal from the output acquisition circuit (e.g., 330 or 330A) after the computing device receives a test completion signal from the prototype system (e.g., 30 or 30A) and to check whether the test of the circuit module (e.g., 310 or 310A) is passed based on the output data associated with the test signal and expected results associated with the test.

In some embodiments of the method for circuit validation, the prototype system (e.g., 30 or 30A) is coupled to the computing device (e.g., 40 or 40A) through a signal interface (e.g., INF; INF1 and INF2), and the input generation circuit (e.g., 320 or 320A) and the output acquisition circuit (e.g., 330 or 330A) are coupled to the computing device (e.g., 40 or 40A) through the signal interface.

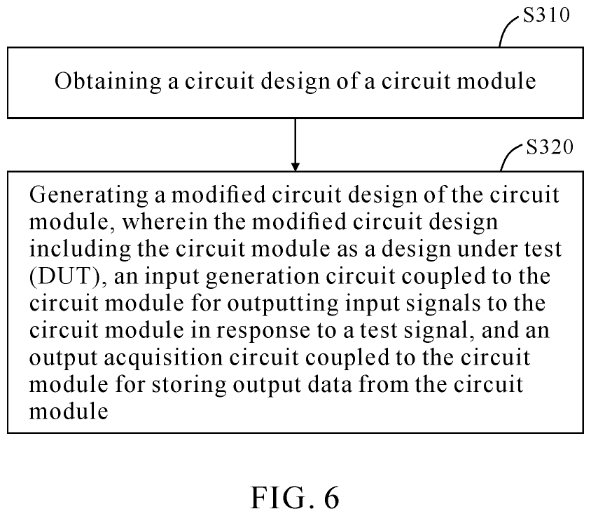

In addition, following embodiments of a method for facilitating circuit validation are provided from another aspect of the present disclosure. FIG. 6 illustrates the method for facilitating circuit validation with respect to a circuit module according to an embodiment. The method in FIG. 6 is a generalized process including steps S310 and S320.

Step S310 includes obtaining, by a computing device, a circuit design of a circuit module. For example, the circuit design (e.g., 210 corresponding to 310 (or 310A)) of a circuit module (e.g., first circuit modules 150 and 160; or second circuit modules 170 and 180) may be a portion of a circuit design (e.g., 10) of a digital circuit system (e.g., 101).

Step S320 includes generating, by the computing device, a modified circuit design (e.g., 210, 220, 230) of the circuit module, wherein the modified circuit design including the circuit module (e.g., 210 corresponding to 310 (or 310A)) as a design under test (DUT), an input generation circuit (e.g., 220 corresponding to 320 (or 320A)) coupled to the circuit module for outputting input signals to the circuit module in response to a test signal, and an output acquisition circuit (e.g., 230 corresponding to 330 (or 330A)) coupled to the circuit module for storing output data from the circuit module.

At steps S310 and S320, the computing device, for example, can be any appropriate computing device for executing an electronic design automation (EDA) tool (e.g., 20) or performing operations on a circuit design according to the method of FIG. 6, such as a computer, workstation, server, or a cloud system, or so on. The EDA tool can be configured to perform the method of FIG. 6. For example, any of the related examples of the EDA tool 20 in the present disclosure can be applied to the method of FIG. 6 as an embodiment of the method, whenever appropriate. For example, obtaining a circuit design of a circuit module or generating a modified circuit design of the circuit module can be implemented according to one of the examples related to the method of FIG. 2 for prototyping a circuit design of a circuit module as illustrated above.

In some embodiments of the method for facilitating circuit validation, the modified circuit design (e.g., 210, 220, 230) of the circuit module is generated for configuring a prototype system (e.g., or 30A) comprising a programming logic device circuit (e.g., 301 or 301A) to implement the modified circuit design.

Further, following embodiments of a system for facilitating circuit validation are provided from another aspect of the present disclosure. The system for facilitating circuit validation comprises a prototype system (e.g., 30 or 30A) which includes a programming logic device circuit (e.g., 301 or 301A) configured to implement a modified circuit design (e.g., 210, 220, 230). The modified circuit design includes a circuit module (e.g., 210 corresponding to 310 (or 310A)) as a design under test (DUT), an input generation circuit (e.g., 220 corresponding to 320 (or 320A)) coupled to the circuit module for outputting input signals to the circuit module in response to a test signal, and an output acquisition circuit (e.g., 230 corresponding to 330 (or 330A)) coupled to the circuit module for storing output data from the circuit module.

For example, any of the related examples of the prototype system (e.g., 30 or 30A) in the present disclosure can be applied to the system for facilitating circuit validation as an embodiment of the system, whenever appropriate.

In some embodiments of the method or system for facilitating circuit validation, the prototype system (e.g., 30 or 30A) is configured to be capable of being communicated with a test computing device (e.g., 40 or 40A) and configured to perform a test of the DUT on the prototype system in response to a test signal from the test computing device (e.g., 40 or 40A). The test computing device, for example, can be any appropriate computing device for performing operations such as operations performed by a test program (e.g., 41 or 41A) for controlling the prototype system (e.g., or 30A) for circuit validation, and the test computing device can be such as a computer, workstation, server, or a cloud system, or so on.

In some embodiments of the method or system for facilitating circuit validation, the input generation circuit (e.g., 320 or 320A) is configured to receive the test signal in form of parameters and to output the input signals indicating test patterns corresponding to the parameters for the test of the DUT.

In some embodiments of the method or system for facilitating circuit validation, the output acquisition circuit (e.g., 330 or 330A) is configured to send output data associated with the test signal after the prototype system (e.g., 30 or 30A) sends a test completion signal so that the test computing device (e.g., 40 or 40A) is capable of checking the output data associated with the test signal.

With respect to “asserting” (or an alternative thereof, such as “asserted” or “assertion”) of a signal, it means that the signal is set to an active state (or active voltage level), which may be set to a high or low level. With respect to “de-asserting” (or an alternative thereof, such as “de-asserted” or “de-assertion”) of the signal, it means that the signal is set to an inactive state (or inactive voltage level), which may be set to a high or low level. If the signal is active-low, the signal is “asserting” that means setting the signal to a low level and the signal is “de-asserting” that means setting the signal to a high level. If the signal is active-high, the signal is “asserting” that means setting the signal to a high level and the signal is “de-asserting” that means setting the signal to a low level.

While the present disclosure has been described by way of preferable embodiments, those skilled in the art should understand the above description is merely embodiments of the disclosure, and it should not be considered to limit the scope of the disclosure. It should be noted that all changes and substitutions which come within the meaning and range of equivalency of the embodiments are intended to be embraced in the scope of the disclosure.

What is claimed is:

1. A system for circuit validation, comprising:
a prototype system comprising a programming logic device circuit configured to implement a modified circuit design including
a circuit module as a design under test (DUT),
an input generation circuit coupled to the circuit module for outputting input signals to the circuit module in response to a test signal, and
an output acquisition circuit coupled to the circuit module for storing output data from the circuit module; and
a computing device capable of being coupled to the prototype system and configured to generate the test signal to perform a test of the DUT on the prototype system.

2. The system for circuit validation according to claim 1, wherein the computing device is configured to generate the test signal in form of parameters and send the test signal to the input generation circuit to output the input signals indicating test patterns associated with the parameters for the test of the DUT.

3. The system for circuit validation according to claim 1, wherein the computing device is configured to read output data associated with the test signal from the output acquisition circuit after the computing device receives a test completion signal from the prototype system so that the computing device is capable of checking the output data associated with the test signal.

4. The system for circuit validation according to claim 1, wherein the computing device is configured to read output data associated with the test signal from the output acquisition circuit after the computing device receives a test completion signal from the prototype system and to check whether the test of the circuit module is passed based on the output data associated with the test signal and expected results associated with the test.

5. The system for circuit validation according to claim 1, wherein the prototype system is coupled to the computing device through a signal interface, and the input generation circuit and the output acquisition circuit are coupled to the computing device through the signal interface.

6. A method for circuit validation, comprising:
using a prototype system comprising a programming logic device circuit configured to implement a modified circuit design including a circuit module as a design under test (DUT), an input generation circuit coupled to the circuit module for outputting input signals to the circuit module in response to a test signal, and an output acquisition circuit coupled to the circuit module for storing output data from the circuit module; and
communicating with the prototype system by a computing device configured to generate the test signal to perform a test of the DUT on the prototype system.

7. The method for circuit validation according to claim 6, wherein the computing device is configured to generate the test signal in form of parameters and send the test signal to the input generation circuit to output the input signals indicating test patterns corresponding to the parameters for the test of the DUT.

8. The method for circuit validation according to claim 6, wherein the computing device is configured to read output data associated with the test signal from the output acquisition circuit after the computing device receives a test completion signal from the prototype system so that the computing device is capable of checking the output data associated with the test signal.

9. The method for circuit validation according to claim 6, wherein the computing device is configured to read output data associated with the test signal from the output acquisition circuit after the computing device receives a test completion signal from the prototype system and to check whether the test of the circuit module is passed based on the output data associated with the test signal and expected results associated with the test.

10. The method for circuit validation according to claim 6, wherein the prototype system is coupled to the computing device through a signal interface, and the input generation circuit and the output acquisition circuit are coupled to the computing device through the signal interface.

11. A system for facilitating circuit validation, comprising:
a prototype system comprising a programming logic device circuit configured to implement a modified circuit design including
a circuit module as a design under test (DUT);
an input generation circuit coupled to the circuit module for outputting input signals to the circuit module in response to a test signal; and
an output acquisition circuit coupled to the circuit module for storing output data from the circuit module.

12. The system for facilitating circuit validation according to claim 11, wherein the prototype system is configured to be capable of being communicated with a test computing device and configured to perform a test of the DUT on the prototype system in response to a test signal from the test computing device.

13. The system for facilitating circuit validation according to claim 12, wherein the input generation circuit is configured to receive the test signal in form of parameters and to output the input signals indicating test patterns corresponding to the parameters for the test of the DUT.

14. The system for facilitating circuit validation according to claim 12, wherein the output acquisition circuit is configured to send output data associated with the test signal after the prototype system sends a test completion signal so that the test computing device is capable of checking the output data associated with the test signal.

15. A method for facilitating circuit validation, comprising:
obtaining, by a computing device, a circuit design of a circuit module; and
generating, by the computing device, a modified circuit design of the circuit module, wherein the modified circuit design including the circuit module as a design under test (DUT), an input generation circuit coupled to the circuit module for outputting input signals to the circuit module in response to a test signal, and an output acquisition circuit coupled to the circuit module for storing output data from the circuit module.

16. The method for facilitating circuit validation according to claim 15, wherein the modified circuit design of the circuit module is generated for configuring a prototype system comprising a programming logic device circuit to implement the modified circuit design, wherein the prototype system is configured to be capable of being communicated with a test computing device and configured to perform a test of the DUT on the prototype system in response to a test signal from the test computing device.

17. The method for facilitating circuit validation according to claim 16, wherein the input generation circuit is configured to receive the test signal in form of parameters and to output the input signals indicating test patterns corresponding to the parameters for the test of the DUT.

18. The method for facilitating circuit validation according to claim 16, wherein the output acquisition circuit is configured to send output data associated with the test signal after the prototype system sends a test completion signal so that the test computing device is capable of checking the output data associated with the test signal.
